(19) United States
(12) Patent Application Publication
(10) Pub. No.: US 2017/0263827 A1
(43) Pub. Date: Sep. 14, 2017

(54) RESIN DISPENSING APPARATUS

(71) Applicant: SAMSUNG ELECTRONICS CO., LTD., Suwon-si (KR)

(72) Inventors: Young Hyo EUN, Asan-si (KR); Jae Sung KIM, Yongin-si (KR); Ju Hyun SONG, Cheonan-si (KR); Tae Hee SONG, Gunpo-si (KR); Shin Min RHEE, Seoul (KR); Ji Yeon HAN, Asan-si (KR)

(73) Assignee: SAMSUNG ELECTRONICS CO., LTD., Suwon-si (KR)

(21) Appl. No.: 15/344,892

(22) Filed: Nov. 7, 2016

(30) Foreign Application Priority Data
Mar. 14, 2016 (KR) 10-2016-0030152

(51) Int. Cl. H01L 33/56; B05B 1/34; H01L 33/50

(52) U.S. Cl. CPC H01L 33/56; H01L 33/507; B05B 1/34; H01L 2933/005; H01L 2933/0041; H01L 33/502; H01L 21/67126

(57) ABSTRACT

A resin dispensing apparatus is provided. The resin dispensing apparatus includes an external body portion including a discharge nozzle configured to discharge a phosphor-containing resin, and an internal body portion including at least one flow passage, the internal body portion being mounted within the external body portion. An axial length of the internal body portion is shorter than an axial length of the external body portion.

### CROSS-REFERENCE TO RELATED APPLICATION

This application claims priority from Korean Patent Application No. 10-2016-0030152 filed on Mar. 14, 2016 in the Korean Intellectual Property Office, the disclosure of which is incorporated herein by reference in its entirety.

### BACKGROUND

1. Field

The present inventive concept relates to a resin dispensing apparatus.

2. Description of Related Art

In the related art, in order to encapsulate light emitting devices with a phosphor-containing resin, resin dispensing apparatuses are configured in such a manner that syringes filled with a predetermined amount of a phosphor-containing resin in a defoamed liquid phase are connected to dispensers. The dispensers are set to discharge the phosphor-containing resin in a predetermined amount.

However, in the above-described resin dispensing apparatuses, a phenomenon in which phosphor particles contained in the phosphor-containing resin sink toward the bottom of the syringe may occur over time. Thus, a problem in which a phosphor is not distributed uniformly in a phosphor-containing resin, due to such sedimentation of phosphor particles, has occurred.

Due to such non-uniform phosphor distribution, a problem in which the dispersion of color coordinates is increased has occurred in manufactured light emitting device packages.

### SUMMARY

An aspect of the present inventive concept is to provide a scheme in which phosphor particles may be prevented from sinking in a phosphor-containing resin disposed in a syringe.

According to an aspect of the present inventive concept, a resin dispensing apparatus may include: an external body portion including a discharge nozzle configured to discharge a phosphor-containing resin; and an internal body portion including at least one flow passage, the internal body portion being mounted within the external body portion, wherein an axial length of the internal body portion is shorter than an axial length of the external body portion.

According to an aspect of the present inventive concept, a resin dispensing apparatus may include: an external body portion having a single chamber structure storing a phosphor-containing resin, the external body portion configured to discharge the phosphor-containing resin through a discharge nozzle; and an internal body portion including a multi-chamber structure having a plurality of flow passages, the internal body portion being mounted within the external body portion, wherein an axial length of the internal body portion is shorter than an axial length of the external body portion.

According to an aspect of the present inventive concept, a resin dispensing apparatus may include: an external body including: an inlet provided at a first end; and a discharge nozzle provided at a second end opposite to the first end and configured to discharge a phosphor-containing resin; and an internal body detachably attached to an interior of the external body, wherein an axial length of the internal body is shorter than an axial length of the external body, and wherein a cross-sectional area of the interior of the external body is larger than a cross-sectional area of an interior of the internal body.

### BRIEF DESCRIPTION OF DRAWINGS

The above and/or other aspects, features and other advantages of the present disclosure will be more clearly understood from the following detailed description taken in conjunction with the accompanying drawings, in which:

FIG. 1 is a schematic cross-sectional view of a resin dispensing apparatus according to an example embodiment;

FIG. 2 is a cross-sectional view of a resin dispensing apparatus taken along line I-I′ of FIG. 1;

FIG. 3 is a schematic perspective view of an internal body portion according to an example embodiment of the present inventive concept;

FIGS. 4A and 4B are schematic perspective views of internal body portions according to example embodiments;

FIGS. 5A and 5B are schematic perspective views of internal body portions according to example embodiments;

FIGS. 6A and 6B are schematic perspective views of internal body portions according to example embodiments;

FIG. 7 is a graph illustrating a relative amount of a sinking rate of phosphor particles according to a distance from a wall surface, obtained through a simulation;

FIGS. 8A and 8B are graphs illustrating evaluation results of intensity of light of a phosphor in a single chamber and multiple chambers;

FIG. 9 is a graph illustrating a comparison of a defect rate in color coordinates and chromaticity coordinate distribution;

FIG. 10 is a graph illustrating a discharge rate distribution of a phosphor-containing resin;

FIGS. 11A and 11B are schematic cross-sectional views of light emitting device packages, target dispensing objects, according to example embodiments;

FIGS. 12A and 12B are schematic cross-sectional views of light emitting device packages according to example embodiments of the present inventive concept;

FIGS. 13A and 13B are schematic cross-sectional views of light emitting device packages according to example embodiments of the present inventive concept;

FIG. 14 is a schematic cross-sectional view illustrating a process of manufacturing a light emitting device package using a resin dispensing apparatus; and

FIG. 15 is a CIE 1931 color space chromaticity diagram illustrating a phosphor that may be employed in an example embodiment of the present inventive concept.

### DETAILED DESCRIPTION

Hereinafter, example embodiments of the present inventive concept will be described with reference to the accompanying drawings.

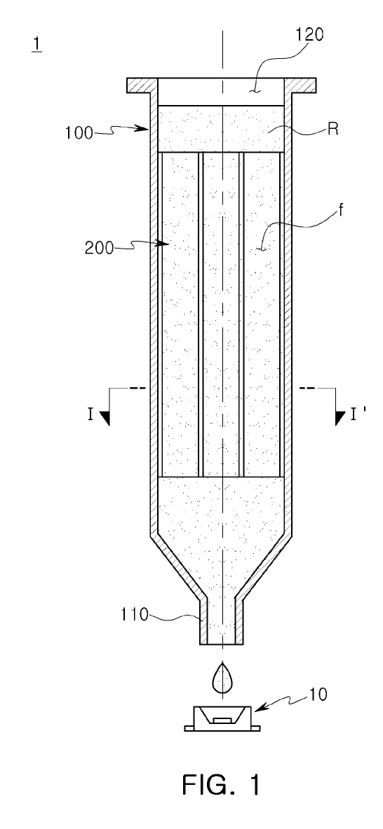

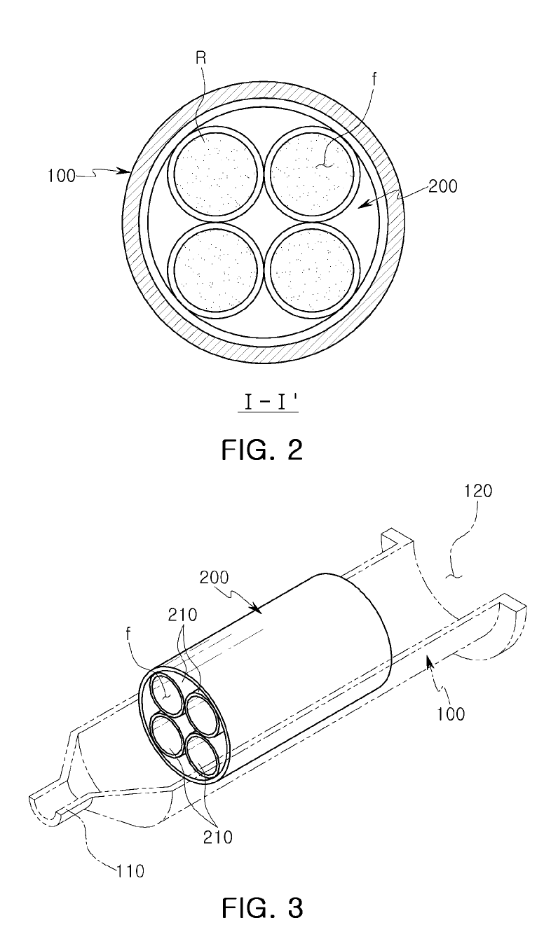

With reference to FIG. 1, a resin dispensing apparatus 1 according to an example embodiment will be described. FIG. 1 is a schematic cross-sectional view of a resin dispensing apparatus according to an example embodiment. FIG. 2 is a cross-sectional view of a resin dispensing apparatus 1 taken along line I-I′ of FIG. 1.

With reference to FIGS. 1 and 2, a resin dispensing apparatus 1 according to an example embodiment may include an external body portion 100 and an internal body portion 200 mounted within the external body portion 100. The resin dispensing apparatus 1 may discharge a phosphor-containing resin R, accommodated in the interior thereof, to a target dispensing object, for example, a light emitting device package 10, to coat the light emitting device package 10 therewith.

The external body portion 100 may have a single chamber structure and accommodate the phosphor-containing resin R therein. The external body portion 100 may have a discharge nozzle 110 disposed on one end thereof, and may discharge the phosphor-containing resin R externally. The external body portion 100 may have an opening 120 formed in the other end thereof. The phosphor-containing resin R may be injected into the external body portion 100 through the opening 120.

The external body portion 100 may have a pipe shape (e.g., a cylindrical shape)extended in a length direction (i.e., an axial direction) of the resin dispensing apparatus 1. The discharge nozzle 110 may be disposed on a lower end of the external body portion 100, and the opening 120 may be disposed in an upper end portion thereof. The external body portion 100 may take a form of, for example, a syringe.

The example embodiment illustrates that the external body portion 100 has a cylindrical shape having a circular cross section, but the example embodiment is not limited thereto. For example, a cross section of the external body portion 100 may have various shapes such as a quadrangular shape, a pentagonal shape, a hexagonal shape, and the like.

The internal body portion 200 may be mounted within the external body portion 100, to be separable therefrom. That is, the internal body portion 200 may be detachably attached to the external body portion 100. For example, the internal body portion 200 may be inserted into the external body portion 100 through the opening 120.

The internal body portion 200 may be mounted within the external body portion 100, in a manner in which an outer surface of the internal body portion 200 is in contact with an inner surface of the external body portion 100. The internal body portion 200 may have a length (in the axial direction) shorter than that of the external body portion 100, and may be disposed in a substantially central region of the external body portion 100 as shown in FIG. 1.

The internal body portion 200 may have a multi-chamber structure having one or more flow passages f therein.

The one or more flow passages f may be extended in a length direction (i.e., in the axial direction) of the internal body portion 200 and both ends in the length direction of the internal body portion 200 may be open. In detail, the entirety of the internal body portion 200 may have a conduit structure of which two ends are open, and an interior of the internal body portion 200 may include a multi-chamber structure divided into a plurality of flow passages (f).

In a state in which the internal body portion 200 is mounted within the external body portion 100, the external body portion 100 may have a dual-region structure having a multi-chamber structure implemented by the internal body portion 200 and a single chamber structure in an area in which the internal body potion 200 is not provided.

With reference to FIGS. 3 to 6B, the internal body portion 200 will be described in detail. FIG. 3 is a schematic perspective view of an internal body portion 200 according to an example embodiment of the present inventive concept;

In FIG. 3, an internal body portion 200 according to an example embodiment is schematically illustrated.

With reference to FIG. 3, the internal body portion 200 may include a plurality of pipes 210 of which each inner diameter is, for example, about 6 mm, which is less than, for example, about 15.6 mm of an inner diameter of the external body portion 100, and of which two ends of each pipe 210 are open. The interior of each pipe 210 may correspond to the flow passage f. According to an example embodiment, the exterior of the pipe 210 may also correspond to the flow passage f along with the interior of each pipe 210.

The plurality of pipes 210 may be arranged in such a manner that adjacent pipes are in contact with one another in a length direction of the external body portion 100.

The example embodiment illustrates a structure in which four (4) pipes 210 are arranged in FIG. 3, but the example embodiment is not limited thereto. For example, the internal body portion 200 may include five (5) or more pipes 210 or less than four (4) pipes 210.

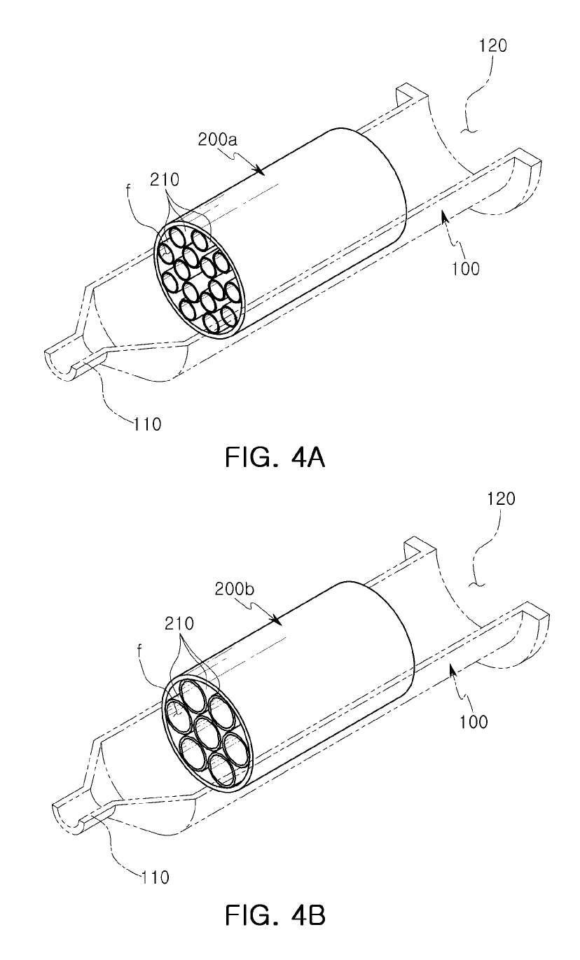

FIGS. 4A and 4B illustrate internal body portions 200a and 200b having structures in which pipes 210 having various diameters are arranged.

As illustrated in FIG. 4A, the internal body portion 200a may have a structure in which a plurality of pipes 210, for example, 15 pipes, having an inner diameter of about 3 mm are arranged. As illustrated in FIG. 4B, the internal body portion 200b may have a structure in which a plurality of pipes 210, for example, 7 pipes, having an inner diameter of about 5 mm are arranged.

As such, the number of the plurality of pipes 210 may be variously changed depending on the inner diameter of respective pipes 210.

The example embodiment illustrates that the plurality of pipes 210 arranged within the external body portion 100 have the same diameter by way of example, but the example embodiment is not limited thereto. For example, the plurality of pipes 210 in the internal body portion 200 may have different diameters.

In addition, the example embodiment illustrates that cross sections of the plurality of pipes 210 have a circular shape by way of example, but the example embodiment is not limited thereto. For example, cross sections of the plurality of pipes 210 may have various shapes such as substantially pentagonal, hexagonal, and honeycomb shapes.

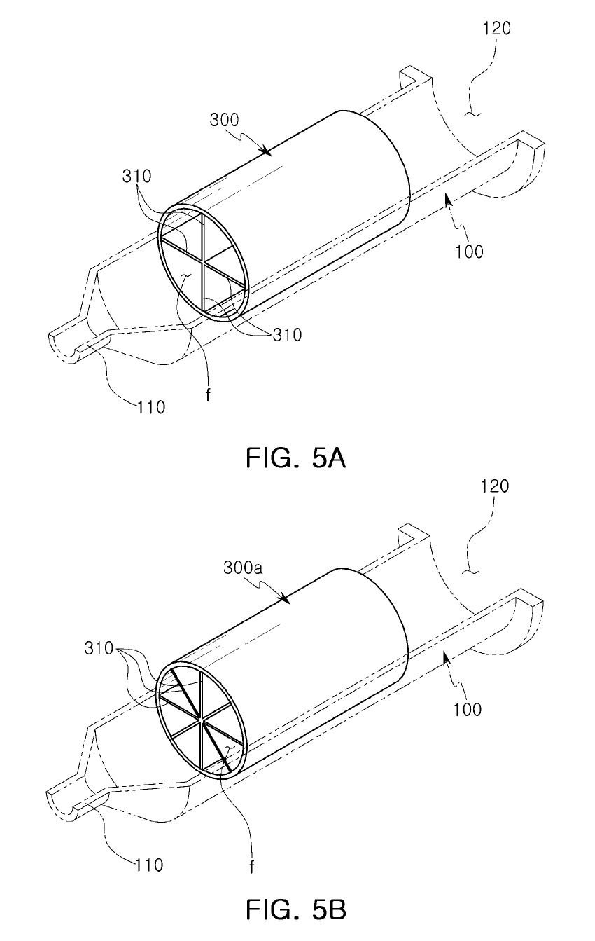

FIGS. 5A and 5B schematically illustrate internal body portions 300 and 300a according to example embodiments of the present inventive concept.

With reference to FIGS. 5A and 5B, an internal body portion 300 may include a plurality of separation plates 310 radially extending from a central axis extending in a length direction (i.e., the axial direction) of the internal body portion 300.

The plurality of separation plates 310 may divide a single space within the internal body portion 300 having a conduit structure, of which two ends are open, into a plurality of spaces, based on the central axis. The divided spaces may be defined as a plurality of flow passages f extended in a length direction of the internal body portion 300, respectively.

As illustrated in FIG. 5A, the internal body portion 300 may be divided into four (4) spaces by the separation plates 310, to thus have four flow passages f. As illustrated in FIG. 5B, an internal space of an internal body portion 300a may be divided into eight (8) spaces by the separation plates 310, to thus have eight (8) flow passages f. The number of the flow passages f may be changed by the separation plates 310.

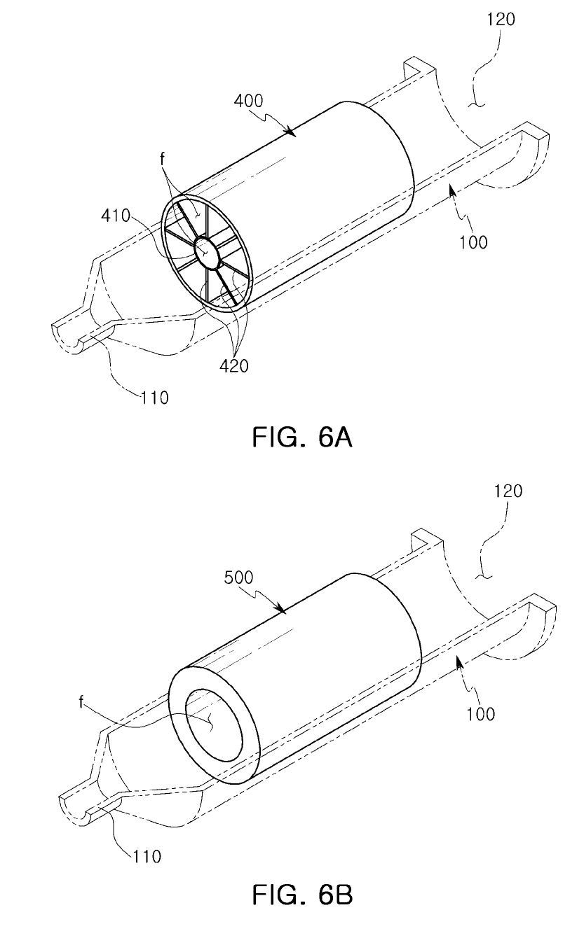

FIG. 6A is a schematic perspective view of an internal body portion 400 according to an example embodiment of the present inventive concept.

With reference to FIG. 6A, an internal body portion 400 may include a pipe 410, of which an inner diameter is less than that of the external body portion 100 and of which two ends are open, and a plurality of separation plates 420 extended radially, from the pipe 410.

The pipe 410 may be disposed in a central portion of the internal body portion 400, to be extended in parallel with the internal body portion 400. The plurality of separation plates 420 may be disposed between the internal body portion 400 and the pipe 410, to connect the internal body portion 400 and the pipe 410 to each other. The plurality of separation plates 420 may divide a single space between the internal body portion 400 and the pipe 410, into a plurality of spaces.

The plurality of spaces divided by the plurality of separation plates 420 and an internal space of the pipe 410 may be extended in a length direction of the internal body portion 400 while being defined as a plurality of flow passages f.

FIG. 6B is a schematic perspective view of an internal body portion 500 according to an example embodiment of the present inventive concept.

With reference to FIG. 6B, an internal body portion 500 may have a single chamber structure, of which an inner diameter is less than that of the external body portion 100 and of which two ends are open. In detail, the internal body portion 500 may have a single flow passage f in a manner similar to the external body portion 100, while having a structure in which an inner diameter thereof is about 9 mm, which is less than about 15.6 mm of an inner diameter of the external body portion 100. Thus, a structure in which a flow passage of the external body portion 100 is partially reduced may be implemented.

The external body portion 100 according to the example embodiment may have a multi-chamber region implemented by the internal body portion 200 and a single chamber region in an area in which the internal body portion 200 is not provided. As such, as the external body portion 100 receiving the phosphor-containing resin R therein has a dual-region structure, the occurrence of sedimentation of phosphor particles in the phosphor-containing resin R may be prevented. For example, the phosphor-containing resin R may have a liquid phase form in which at least one type of phosphor is mixed with a silicone resin or an epoxy resin.

The phosphor-containing resin R may be injected into the external body portion 100 through the opening 120 of the external body portion 100. A phosphor contained in the phosphor-containing resin R may sink toward a lower portion of the external body portion 100 over time. In the case that the agglomeration of phosphor particles occurs as described above, a content of a phosphor in the phosphor-containing resin R discharged through the discharge nozzle 110 is not constant, and a difference in the content may occur over time. This may cause an increase in chromaticity coordinate distribution of a light emitting device package produced as a final product.

In order to solve such a problem, in the example embodiment, as a multi-chamber structure is implemented through the internal body portion 200 within the external body portion 100 having a single chamber structure, the sedimentation of phosphor particles may be suppressed and an increase in chromaticity coordinate distribution may be significantly reduced.

In detail, according to Poiseuille's Law defining the law with respect to a flow rate of a viscous fluid flowing in a conduit, an amount of fluid Q flowing through a circular conduit, per unit time, is proportional to a radius (r) of a conduit raised to the 4th power and a pressure difference ΔP between two ends of the conduit, and is inversely proportional to a length (l) and viscosity (η) of fluid.

$$Q = \frac{π {r}^{4} Δ P}{8 η l}$$

For example, as the radius (r) of a conduit is reduced, the amount Q of fluid flowing through the conduit is reduced. In the example embodiment, as within a single conduit having a predetermined inner diameter, a plurality of pipes having an inner diameter less than the inner diameter of the single conduit are disposed, as a result, a structure in which the inner diameter of the conduit is reduced may be implemented.

In the example embodiment, the phosphor-containing resin R injected into the external body portion 100 may pass through the plurality of flow passages f implemented by the multi-chamber structure of the internal body portion 200. Because an inner diameter of the internal body portion is reduced as compared to a single flow passage of the external body portion 100, an amount of the phosphor-containing resin R flowing in the respective flow passages f may be reduced.

As such, the reduction in the amount of the phosphor-containing resin R flowing in the plurality of flow passages f may provide an effect of relieving sedimentation of phosphor particles.

Phosphor particles contained in a liquid phase resin sink toward a lower portion of an external body portion over time. In this case, as the phosphor particles sinking in the fluid (resin) receive resistance by a wall effect on an inner wall of the chamber forming a flow passage, a sinking rate of the phosphor particles is reduced.

Such a wall effect increases as a distance from a wall is reduced. In the example embodiment, by implementing a multi-chamber structure having a plurality of wall surfaces through the internal body portion, the wall effect may be significantly increased. In detail, in the example embodiment, a single flow passage having a predetermined inner diameter is divided into a plurality of flow passages having an inner diameter less than the inner diameter of the single flow passage. In this case, a wall effect may be generated in respective flow passages, the sedimentation of phosphor particles may be relieved. In addition, because an amount of the phosphor-containing resin R flowing in the respective flow passages is reduced, the reduction in the sedimentation of phosphor particles may be further effective.

Further, in order to improve the wall effect, a concave-convex structure may be formed on a surface of multiple chambers forming flow passages f, for example, on surfaces of the pipes 210 or the separation plates 310. The concave-convex structure may protrude, for example, in an embossed form, to increase a contact area with the phosphor-containing resin R.

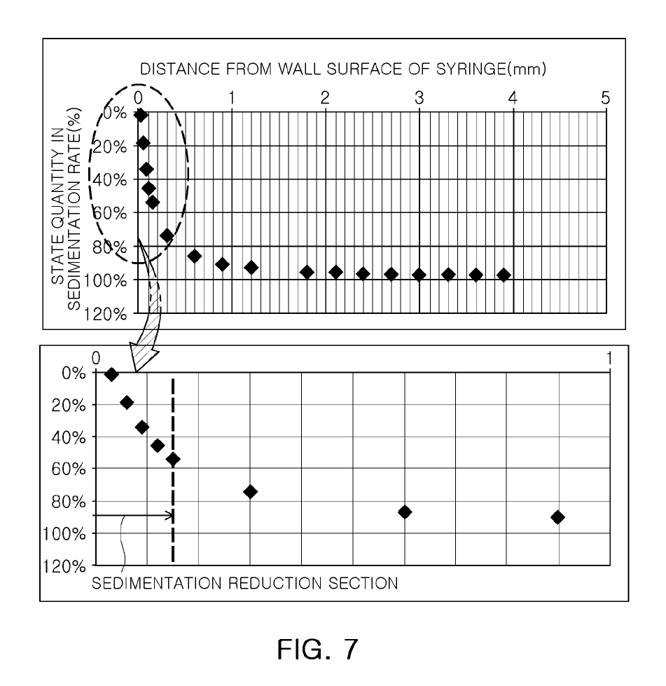

FIG. 7 is a graph illustrating a relative amount of a sinking rate of phosphor particles, based on a distance from a wall surface, obtained through a simulation.

With reference to FIG. 7, it can be confirmed that the sedimentation of phosphor particles is alleviated in a region in which a distance from a wall surface is about 0.15 mm, by the wall effect, (sedimentation reduction section). In addition, it can be appreciated that because resistance by the wall effect is reduced away from a wall surface, a sedimentation reduction effect is reduced.

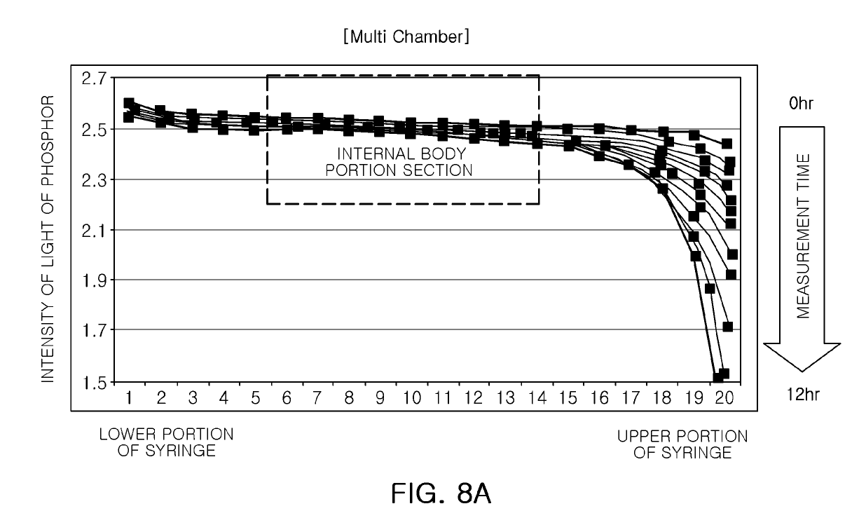

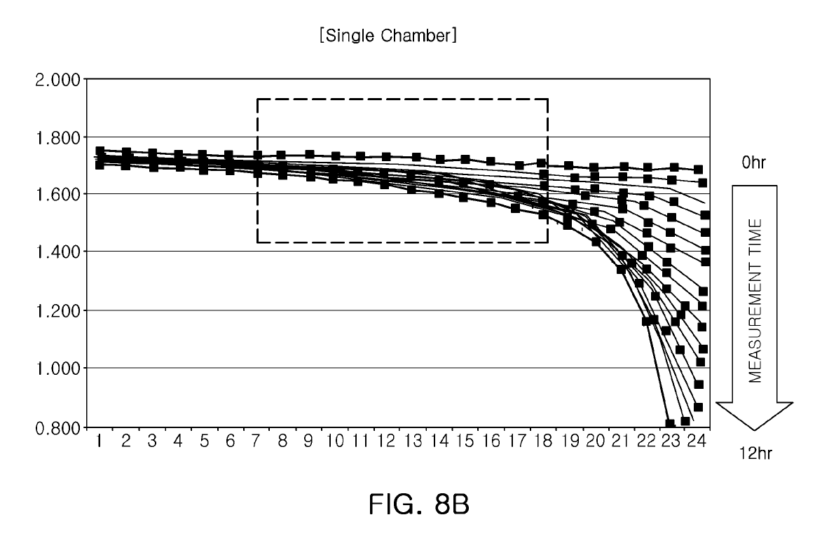

FIGS. 8A and 8B are graphs respectively illustrating evaluation results of intensity of light of a phosphor in a single chamber and multiple chambers.

The evaluation of the intensity of light of a phosphor may be performed, by allowing ultraviolet light to be irradiated onto a syringe into which the phosphor-containing resin has been injected and by measuring a degree of visible light emitted by being excited from the phosphor using a phosphor photometer.

The evaluation was carried out on a syringe having a single chamber structure and a syringe having a multi-chamber structure, under the same conditions, respectively. The syringe having a single chamber structure was configured to have an inner diameter of about 15.6 mm, and the syringe having a multi-chamber structure was configured to have an internal body portion in which 10 chambers each having an inner diameter of about 3 mm are disposed. In an evaluation method, the intensity of light of a phosphor was measured with the respective syringes, 144 times, for 12 hours.

First, as illustrated in FIG. 8A, in the case of the syringe having a multi-chamber structure, it can be confirmed that a change in phosphor light intensity was relatively low in an internal body portion represented by a dotted line. This indicates that the sedimentation of phosphor particles was suppressed or relieved by the wall effect. As in the example embodiment, it can be appreciated that an effect of reducing or suppressing sedimentation of phosphor particles is provided in the multi-chamber structure.

Meanwhile, as illustrated in FIG. 8B, in the case of the syringe having a single chamber structure, it can be confirmed that a relatively great change in phosphor light intensity was present in a region of the syringe, represented by a dotted line and corresponding to the region of FIG. 8A in which the internal body portion is disposed. This indicates that a degree of sedimentation of phosphor particles was relatively high, as compared to the multi-chamber structure.

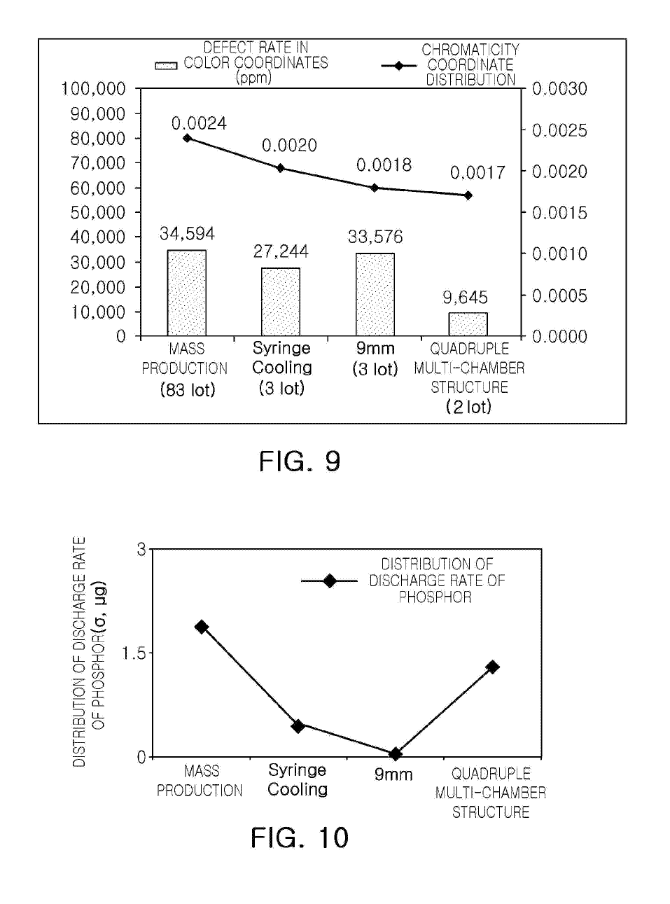

FIG. 9 is a graph illustrating comparison of a defect rate in color coordinates and chromaticity coordinate distribution. In detail, in connection with the structure of a syringe, defect rates in respective color coordinates and color coordinate distribution in two comparative examples and two example embodiments are illustrated through the graph of FIG. 9.

In Comparative Example 1, an existing mass-produced syringe having an inner diameter of about 15.6 mm was used. In Comparative Example 2, a syringe was cooled. Embodiment 1 provides a result with respect to a case in which an internal body portion having a single chamber structure, of which an inner diameter is about 9 mm, is formed within an existing mass-produced syringe. Embodiment 2 provides a result with respect to a case in which an internal body portion having a quadruple multi-chamber structure, of which an inner diameter is about 6 mm (as shown in FIG. 3), is formed in an existing mass-produced syringe.

From results with respect to the color coordinate distribution, it can be confirmed that Embodiment 2 employing the multi-chamber structure provides a most excellent result and Embodiment 1 having a structure in which an inner diameter is reduced provides an excellent result as compared to an existing mass-produced syringe.

From results with respect to defect rates in color coordinates, it can be confirmed that Embodiment 2 having the multi-chamber structure has a most excellent result. In addition, it can be confirmed that excellent results are provided in order of Comparative Example 2 and Embodiment 1.

FIG. 10 is a graph illustrating a discharge rate distribution of a phosphor-containing resin. In the discharge rate distribution, the dispersion of a discharge rate was reduced in order of Embodiment 1, Comparative Example 2, and Embodiment 2. Thus, it can be appreciated that Embodiment 1, Comparative Example 2, and Embodiment 2 have excellent results, as compared to results in Comparative Example 1 employing an existing mass-produced syringe.

As such, in the example embodiment, as an internal body portion having a multi-chamber structure is provided within an external body portion having a single chamber structure, an effect of suppressing or reducing the sedimentation of phosphor particles may be obtained as compared to an existing mass-produced syringe only having a single chamber structure. As the sedimentation of phosphor particles is suppressed or relieved, the dispersion of color coordinates and a defect rate in a light emitting device package manufactured as a final product may be reduced.

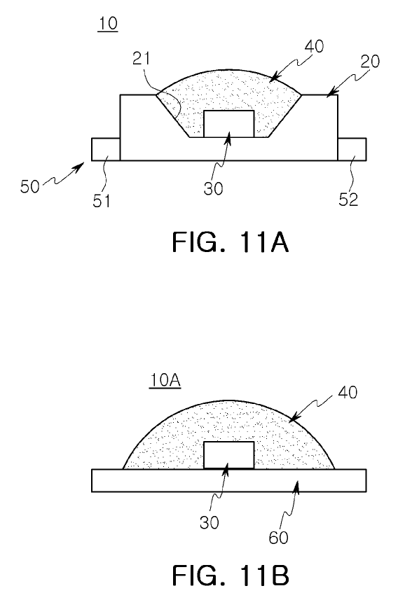

With reference to FIGS. 11A and 11B, a target dispensing object will be described below. FIGS. 11A and 11B are schematic cross-sectional views of light emitting device packages, target dispensing objects, according to example embodiments.

The target dispensing object may be a light emitting device or a light emitting device package in which a light emitting device is mounted. The light emitting device may be encapsulated by a phosphor-containing resin R discharged from the resin dispensing apparatus 1. Hereinafter, an example in which the target dispensing object is a light emitting device package 10 will be described.

With reference to FIG. 11A, the light emitting device package 10 according to an example embodiment may have a package structure in which a light emitting device 30 is mounted within a package body portion 20 having a reflective cup. The light emitting device 30 may be covered by an encapsulation member 40 formed of a resin containing a phosphor.

The package body portion 20 may serve as a base member on which the light emitting device 30 is mounted and supported thereby, and may be formed of a white molding compound having relatively high light reflectivity. The use of the white molding compound provides an effect of reflecting light emitted from the light emitting device 30 to increase an amount of light emitted externally.

The white molding compound may include a thermosetting resin-based material having high heat resistance or a silicone resin-based material. In addition, in the white molding compound, a white pigment and a filling material, a hardener, a releasing agent, an antioxidant, an adhesion improver, or the like may be added to a thermoplastic resin-based material. In addition, the package body portion 12 may also be formed of FR-4, CEM-3, an epoxy material, a ceramic material, or the like. Further, the package body portion 20 may be formed using a metal.

The package body portion 20 may be provided with a lead frame 50 disposed thereon, for electrical connection of the light emitting device 30 to external power. The lead frame 50 may be formed using a material having excellent electrical conductivity, for example, a metal such as aluminum (Al), copper (Cu), or the like.

The lead frame 50 may be disposed to have a structure in which at least one pair of lead frames are separated from each other to oppose each other, to obtain electrical insulation. For example, the lead frame 50 may include a first lead frame 51 having a first polarity and a second lead frame 52 having a second polarity different from the first polarity. In this case, the first polarity and the second polarity may be a positive and a negative, respectively, or vice versa. The first lead frame 51 and the second lead frame 52 are separated from each other and electrically insulated from each other by the package body portion 20.

Bottom surfaces of the first and second lead frames 51 and 52 may be externally exposed through a bottom surface of the package body portion 20. Thus, heat generated in the light emitting device 30 may be discharged externally, to improve a heat radiation effect.

The package body portion 20 may have a reflective cup 21 recessed into an upper surface of the package body portion 20 to a predetermined depth. The reflective cup 21 may have a cup structure in which an inner side surface thereof is tapered toward a bottom surface of the package body portion 20. An area of an upper portion of the reflective cup 21 exposed to an upper part of the package body portion 20 may be defined as a light emission surface of the light emitting device package 10.

The first and second lead frames 51 and 52 may be partially exposed to a bottom surface of the reflective cup 21. The light emitting device 30 may be electrically connected to the first and second lead frames 51 and 52.

The light emitting device 30 may be an optoelectronic device generating light having a predetermined wavelength through driving power applied from an external source through the lead frame 50. For example, the light emitting device 30 may include a semiconductor light emitting diode (LED) chip including a first conductivity-type semiconductor layer, a second conductivity-type semiconductor layer, and an active layer disposed therebetween.

The light emitting device 30 may emit blue light, green light, or red light, according to a material contained therein or a combination thereof with a phosphor. The light emitting device 30 may also emit white light, ultraviolet light, or the like.

The encapsulation member 40 may cover the light emitting device 30. The encapsulation member 40 may be formed by allowing the phosphor-containing resin R to be cured.

The encapsulation member 40 may be formed of a transparent or semi-transparent material to allow light generated in the light emitting device 30 to be emitted externally, and for example, may be formed of a resin such as silicone, an epoxy, or the like.

The example embodiment illustrates that the encapsulation member 40 has a dome-shaped lens structure by way of example, but is not limited thereto. The encapsulation member 40 may also be formed to have a flat upper surface to correspond to a shape of an upper surface of the package body portion 20. In addition, a separate lens may be attached to the upper surface thereof.

FIG. 11B illustrates a modified example of the light emitting device package 10, for example, a light emitting device package 10A. For example, as illustrated in FIG. 11B, the light emitting device package 10A may have a chip-on-board (COB) structure in which a light emitting device 30 is mounted on a substrate 60. The light emitting device 30 may be covered by an encapsulation member 40 formed of a resin containing a phosphor.

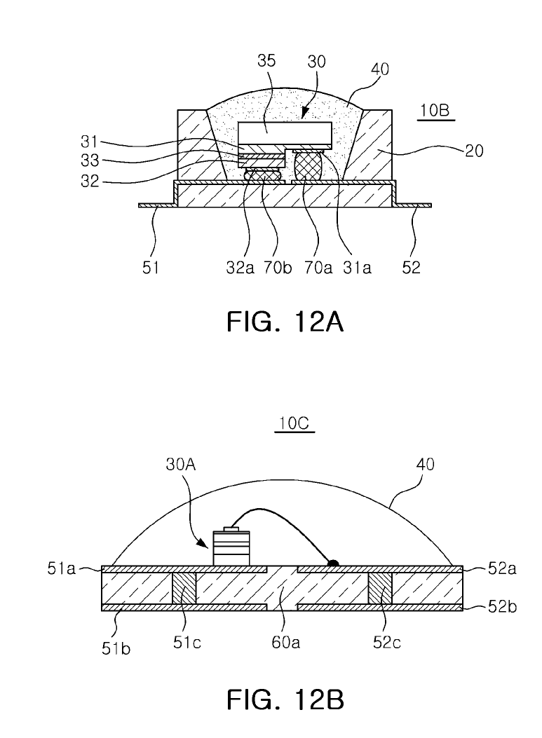

FIGS. 12A and 12B schematically illustrate light emitting device packages according to example embodiments of the present inventive concept. FIGS. 12A and 12B are schematic cross-sectional views of light emitting device packages according to example embodiments.

With reference to FIG. 12A, a light emitting device package 10B manufactured using the resin dispensing apparatus 1 may include a package body portion 20, and a semiconductor light emitting device 30 mounted in the package body portion 20.

The semiconductor light emitting device 30 may include, for example, a substrate 35, a light emitting structure, and first and second electrodes 31a and 32a disposed on the light emitting structure.

The substrate 35 may be provided as a substrate for semiconductor growth, and may be formed of, for example, a material having electrical insulating and conductive properties, such as sapphire, SiC, MgAl₂O₄, MgO, LiAlO₂, LiGaO₂, GaN, or the like.

The light emitting structure may include first and second conductivity-type semiconductor layers 31 and 32, and an active layer 33 disposed therebetween. Although not particularly limited, the first and second conductivity-type semiconductor layers 31 and 32 may be n-type and p-type semiconductor layers, respectively. In the example embodiment, the first and second conductivity-type semiconductor layers 31 and 32 have an empirical formula AlₓIn_{y}Ga(_{1 x y})N (0≦x≦1, 0≦y≦1, 0≦x+y≦1), for example, corresponding to a material such as GaN, AlGaN, InGaN, or the like. The active layer 33 disposed between the first conductivity-type semiconductor layer 31 and the second conductivity-type semiconductor layer 32 may emit light having a predetermined level of energy through a recombination of electrons and holes. The active layer 33 may have a multiple quantum well (MQW) structure in which a quantum well layer and a quantum barrier layer are alternately stacked, for example, an InGaN/GaN structure.

The first and second electrodes 31a and 32a may be formed on the first and second conductivity-type semiconductor layers 31 and 32, respectively, and may be formed of one or more selected from a group consisting of a conductive material used in the art, such as silver (Ag), aluminum (Al), nickel (Ni), chromium (Cr), copper (Cu), gold (Au), palladium (Pd), platinum (Pt), tin (Sn), tungsten (W), rhodium (Rh), indium (Ir), ruthenium (Ru), magnesium (Mg), zinc (Zn), and titanium (Ti), and alloys thereof.

The package body portion 20 may include first and second lead frames 51 and 52. The package body portion 20 may serve to support the first and second lead frames 51 and 52, and may be formed of an opaque material or a resin having relatively high reflectivity. For example, the package body portion 20 may be formed using a polymer resin facilitating an injection molding process. However, a material of the package body portion 20 is not limited thereto. Thus, various types of non-conductive material may be used.

The first and second lead frames 51 and 52 may be formed of a metal having excellent electrical conductivity, and may be electrically connected to the first and second electrodes 31a and 32a of the semiconductor light emitting device 30, to transfer driving power received from an external source, to the semiconductor light emitting device 30.

Although not particularly limited, in the example embodiment, the first and second electrodes 31a and 32a of the semiconductor light emitting device 30 may be disposed to oppose the second lead frame 52 and the first lead frame 51, and may be electrically connected thereto by a medium of first and second bumps 70a and 70b, respectively.

The semiconductor light emitting device 30 may be encapsulated by an encapsulation member 40 formed when a phosphor-containing resin R discharged through the resin dispensing apparatus 1 is cured.

With reference to FIG. 12B, a light emitting device package 10C manufactured using the resin dispensing apparatus 1 may include a package substrate 60a, and a semiconductor light emitting device 30A mounted on the package substrate 60a.

The package substrate 60a may include upper pads 51a and 52a, lower pads 51b and 52b, and penetrating vias 51c and 52c penetrating through the package substrate 60a to electrically connect the upper pads 51a and 52a and the lower pads 51b and 52b to each other, respectively.

The semiconductor light emitting device 30A may include a light emitting structure and first and second electrodes disposed on surfaces of the light emitting structure, opposing each other, respectively, and may have a vertical structure in which the first and second electrodes are disposed on upper and lower surfaces of the light emitting structure, respectively.

The semiconductor light emitting device 30A may be connected to the upper pad 51a, one of the upper pads 51a and 52a, through the second electrode disposed therebelow, and may be connected to another upper pad 52a through the first electrode disposed on an upper portion thereof, using a bonding wire.

The semiconductor light emitting device 30A may be encapsulated by an encapsulation member 40 formed when a phosphor-containing resin R discharged through the resin dispensing apparatus 1 is cured.

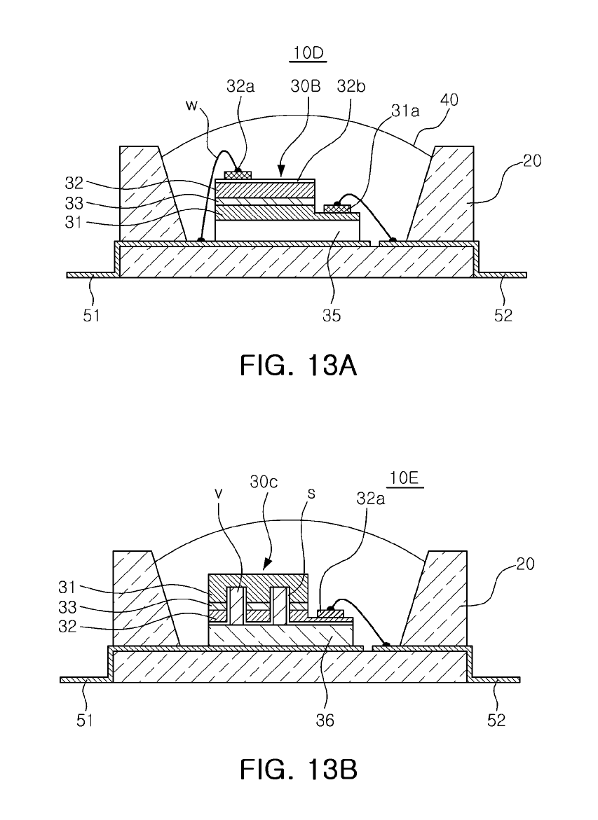

FIGS. 13A and 13B schematically illustrate light emitting device packages according to example embodiments of the present inventive concept. FIGS. 13A and 13B are schematic cross-sectional views of light emitting device packages according to example embodiments.

A light emitting device package 10D illustrated in FIG. 13A may include a semiconductor light emitting device 30B and a package body portion 20. The package body portion 20 may include first and second lead frames 51 and 52. The semiconductor light emitting device 30B may include a substrate 35 and a light emitting structure, which is disposed on the substrate 35 and on which first and second electrodes 31a and 32a are formed. The light emitting structure may include first and second conductivity-type semiconductor layers 31 and 32, and an active layer 33 disposed therebetween. A transparent electrode layer 32b may be disposed between the second conductivity-type semiconductor layer 32 and the second electrode 32a.

In the case of the light emitting device package 10D according to the example embodiment, the first and second electrodes 31a and 32a may respectively be electrically connected to the first and second lead frames 51 and 52 through bonding wires (w), in a manner different from the light emitting device package 10B illustrated in FIG. 12A, rather than being disposed to oppose the first and second lead frames 51 and 52.

The semiconductor light emitting device 30B may be encapsulated by an encapsulation member 40 formed when a phosphor-containing resin R discharged through the resin dispensing apparatus 1 is cured.

A semiconductor light emitting device 30C included in a light emitting device package 10E illustrated in FIG. 13B may include a conductive substrate 36, and a light emitting structure disposed on the conductive substrate 36. The light emitting structure may include a first conductivity-type semiconductor layer 31, an active layer 33, and a second conductivity-type semiconductor layer 32. In the example embodiment, the semiconductor light emitting device 30C may include a conductive via (v) penetrating through the second conductivity-type semiconductor layer 32 and the active layer to be connected to the first conductivity-type semiconductor layer 31. An insulating portion s may be formed on a lateral surface of the conductive via (v) to prevent unnecessary electrical short circuits.

The conductive via (v) may be electrically connected to the conductive substrate 36, and thus, the conductive substrate 36 may perform a function equal to that of the first electrode connected to the first conductivity-type semiconductor layer 31. A second electrode 32a may be disposed on the second conductivity-type semiconductor layer 32. The conductive via (v) may be electrically connected to the first lead frame 51, and the second electrode 32a may be electrically connected to the second lead frame 52 through a bonding wire. In this case, a uniform level of current may be provided to the light emitting structure through the conductive via (v).

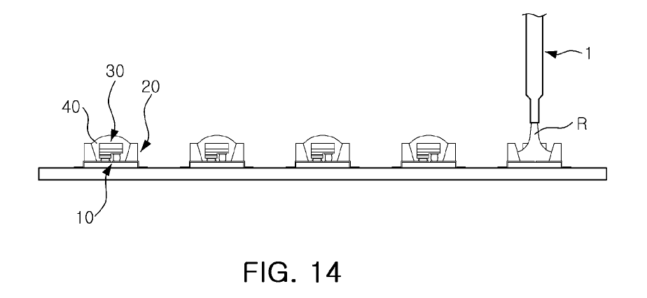

FIG. 14 schematically illustrates a process of manufacturing the light emitting device package 10 using the resin dispensing apparatus 1.

A plurality of package body portions 20 in which a semiconductor light emitting device 30 is respectively mounted may be sequentially disposed below the resin dispensing apparatus 1. Then, the resin dispensing apparatus 1 may discharge a predetermined amount of phosphor-containing resin R to encapsulate the semiconductor light emitting device 30 mounted in respective package body portions 20.

The phosphor-containing resin R encapsulating the semiconductor light emitting device 30 may be formed as an encapsulation member 40 through a curing process.

For example, the encapsulation member 40 may include at least one type of phosphor excited by light generated in the light emitting device 30 to emit light having a different wavelength. Thus, the emission of various colors of light, as well as white light, may be controlled.

For example, when the light emitting device 30 is an LED chip emitting blue light, white light may be emitted thereby through a combination thereof with yellow, green, red and/or orange phosphors. In addition, the light emitting device package may be configured to include at least one of LED chips emitting violet light, blue light, green light, red light, and infrared light. In this case, in the light emitting device 30, a color rendering index (CRI) may be adjusted from ‘40’ to a level of ‘100’ and various types of white light having a color temperature of around 2000K to around 20000K may be generated. In addition, a lighting color may be adjusted to be appropriate for an ambient atmosphere or for viewer mood by generating violet, blue, green, red, orange visible light or infrared light as needed. Further, the light emitting device 30 may emit light within a special wavelength band, capable of promoting plant growth.

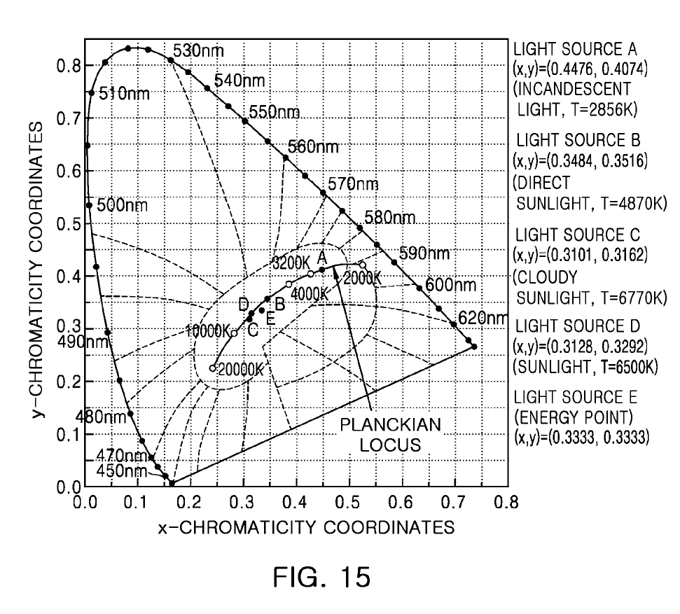

White light obtained by combining yellow, green, red phosphors and/or green and red LED chips with a blue LED chip may have two or more peak wavelengths, and coordinates (x, y) thereof in the CIE 1931 color space chromaticity diagram illustrated in FIG. 15 may be located on line segments (0.4476, 0.4074), (0.3484, 0.3516), (0.3101, 0.3162), (0.3128, 0.3292), and (0.3333, 0.3333) connected to one another. Alternatively, the coordinates (x, y) may be located in a region surrounded by the line segments and blackbody radiation spectrum. A color temperature of the white light may be within a range of around 2000K to around 20000K.

In FIG. 15, white light in the vicinity of a point E (0.3333, 0.3333) below the blackbody radiation spectrum may be in a state in which light of a yellow-based component becomes relatively weak. This white light may be used as an illumination light source of a region in which a relatively bright or refreshing mood is required to be provided to a user. Thus, a lighting product using white light in the vicinity of the point E (0.3333, 0.3333) below the blackbody radiation spectrum may be effective for use in retail spaces in which groceries, clothing, or the like are for sale.

Phosphors may be represented by the following empirical formulae and have a color as below.

Oxide-based Phosphor: Yellow and green Y3Al₅O₁₂:Ce, Tb₃Al₅O₁₂:Ce, Lu₃Al₅O₁₂:Ce

Silicate-based Phosphor: Yellow and green (Ba, Sr)₂SiO₄:Eu, Yellow and yellowish-orange (Ba, Sr)₃SiO₅:Ce

Nitride-based Phosphor: Green β-SiAlON:Eu, yellow La₃Si₆N₁₁:Ce, yellowish-orange α-SiAlON:Eu, CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4) (where Ln is at least one selected from a group consisting of a group IIIa element and a rare-earth element, and M is at least one selected from a group consisting of Ca, Ba, Sr and Mg).

Fluoride-based Phosphor: KSF-based red K₂SiF₆:Mn⁴⁺, K₂TiF₆:Mn⁴⁺, NaYF₄:Mn⁴⁺, NaGdF₄:Mn⁴⁺, K₃SiF₇:Mn⁴⁺

A composition of a phosphor should basically conform to stoichiometry, and respective elements may be substituted with other elements in respective groups of the periodic table of elements. For example, Sr may be substituted with Ba, Ca, Mg, or the like, of an alkaline earth group II, and Y may be substituted with lanthanum-based terbium (Tb), lutetium (Lu), scandium (Sc), gadolinium (Gd), or the like. In addition, Eu or the like, an activator, may be substituted with cerium (Ce), Tb, praseodymium (Pr), erbium (Er), ytterbium (Yb), or the like, according to a required energy level. In addition, an activator may be used alone, or a sub-activator or the like, for modification of characteristics thereof, may additionally be used.

In detail, in the case of a fluoride-based red phosphor, in order to improve reliability thereof at a relatively high temperature/high humidity, a phosphor may be coated with a fluoride not containing manganese (Mn), or a phosphor surface or a fluoride-coated surface of phosphor coated with a fluoride not containing Mn may further be coated with an organic material. In the case of the fluoride-based red phosphor as described above, a narrow full width at half maximum of 40 nm or less may be obtained in a manner different from the case of other phosphors, and thus, the fluoride-based red phosphor may be used in high-resolution TV sets such as UHD TVs.

In addition, as the wavelength conversion material, a quantum dot (QD) or the like may be used as a phosphor substitute or used by being mixed with a phosphor. Alternatively, the quantum dot may be used alone.

The quantum dot (QD) may have a core-shell structure using a group III-V or group II-VI compound semiconductor. For example, the quantum dot may have a core such as a structure of CdSe, InP, or the like, and a shell such as a structure of ZnS, ZnSe, or the like. Further, the QD may include a ligand for stabilization of the core and the shell. For example, the core may have a diameter of approximately 1 nm to 30 nm, in detail, approximately 3 nm to 10 nm. The shell may have a thickness of approximately 0.1 nm to 20 nm, in detail, 0.5 nm to 2 nm.

The quantum dot may implement various colors depending on the size thereof. In detail, in a case in which the quantum dot is used as a phosphor substitute, the quantum dot may be used as a red or green phosphor. In the case of using the quantum dot, a narrow full width at half maximum of, for example, about 35nm may be obtained.

As set forth above, according to example embodiments, a resin dispensing apparatus in which agglomeration of phosphor particles may be prevented is provided.

While example embodiments have been shown and described above, it will be apparent to those skilled in the art that modifications and variations could be made without departing from the scope of the present disclosure as defined by the appended claims.

What is claimed is:

1. A resin dispensing apparatus comprising:
an external body portion including a discharge nozzle configured to discharge a phosphor-containing resin; and
an internal body portion including at least one flow passage, the internal body portion being mounted within the external body portion,
wherein an axial length of the internal body portion is shorter than an axial length of the external body portion.

2. The resin dispensing apparatus of claim 1, wherein the external body portion comprises:
a multi-chamber portion implemented by the internal body portion; and
a single chamber portion in an area surrounding the internal body potion.

3. The resin dispensing apparatus of claim 1, wherein the at least one flow passage extends in an axial direction of the internal body portion, and
wherein a first end of the at least one flow passage and a second end opposite to the first end of the at least one flow passage along the axial direction are open.

4. The resin dispensing apparatus of claim 1, wherein the internal body portion comprises a plurality of pipes, a first end of each pipe and a second end opposite to the first end of each pipe along an axial direction of the internal body portion being open, and
wherein an inner diameter of each pipe of the plurality of pipes is smaller than an inner diameter of the external body portion.

5. The resin dispensing apparatus of claim 4, wherein adjacent pipes of the plurality of pipes are in contact with each other along the axial length direction.

6. The resin dispensing apparatus of claim 1, wherein the internal body portion comprises a plurality of separation plates radially extending from a central axis in an axial direction of the internal body portion.

7. The resin dispensing apparatus of claim 1, wherein an outer surface of the internal body portion is in contact with an inner surface of the external body portion.

8. The resin dispensing apparatus of claim 1, wherein the phosphor-containing resin comprises a silicone resin or an epoxy resin, and
wherein the phosphor-containing resin contains at least one type of phosphor.

9. The resin dispensing apparatus of claim 1, wherein the external body portion has an opening through which the phosphor-containing resin is injected, and
wherein the internal body portion is inserted into the external body portion through the opening, to be mounted.

10. The resin dispensing apparatus of claim 1, further comprising a concave-convex portion formed on a surface of the internal body portion.

11. The resin dispensing apparatus of claim 1, wherein the discharge nozzle is disposed above a target dispensing object, and
wherein the target dispensing object comprises at least one of a light emitting device encapsulated by the phosphor-containing resin discharged through the discharge nozzle and a light emitting device package in which the light emitting device is mounted.

12. A resin dispensing apparatus comprising:
an external body portion having a single chamber structure storing a phosphor-containing resin, the external body portion configured to discharge the phosphor-containing resin through a discharge nozzle; and
an internal body portion including a multi-chamber structure having a plurality of flow passages, the internal body portion being mounted within the external body portion,
wherein an axial length of the internal body portion is shorter than an axial length of the external body portion.

13. The resin dispensing apparatus of claim 12, wherein the internal body portion comprises a plurality of pipes, a first end of each pipe and a second end opposite to the first end of each pipe along an axial direction of the internal body portion being open, and
wherein an inner diameter of each pipe of the plurality of pipes is smaller than an inner diameter of the external body portion.

14. The resin dispensing apparatus of claim 12, wherein the internal body portion comprises a plurality of separation plates radially extending from a central axis in an axial direction of the internal body portion

15. The resin dispensing apparatus of claim 12, wherein an outer surface of the internal body portion is in contact with an inner surface of the external body portion.

16. A resin dispensing apparatus comprising:
an external body comprising:
an inlet provided at a first end; and
a discharge nozzle provided at a second end opposite to the first end and configured to discharge a phosphor-containing resin; and
an internal body detachably attached to an interior of the external body,
wherein an axial length of the internal body is shorter than an axial length of the external body, and
wherein a cross-sectional area of the interior of the external body is larger than a cross-sectional area of an interior of the internal body.

17. The resin dispensing apparatus of claim 16, wherein the external body comprises a syringe, and
wherein the internal body comprises a plurality of pipes.

18. The resin dispensing apparatus of claim 17, wherein an inner diameter of each pipe of the plurality of pipes is smaller than an inner diameter of the external body.

19. The resin dispensing apparatus of claim 17, wherein adjacent pipes of the plurality of pipes are in contact with each other along an axial length direction of the resin dispensing apparatus.

20. The resin dispensing apparatus of claim 16, wherein the internal body comprises a plurality of separation plates radially extending from a central axis in an axial direction of the resin dispensing apparatus.
